(19) United States
(12) Patent Application Publication
(10) Pub. No.: US 2024/0208084 A1
(43) Pub. Date: Jun. 27, 2024

(54) COVER AND ROBOT HAND

(71) Applicant: SINTOKOGIO, LTD., Nagoya-shi, Aichi (JP)

(72) Inventors: Yoshikane TANAAMI, Nagoya-shi (JP); Miyuki HAYASHI, Nagoya-shi (JP)

(73) Assignee: SINTOKOGIO, LTD., Nagoya-shi, Aichi (JP)

(21) Appl. No.: 18/530,087

(22) Filed: Dec. 5, 2023

(30) Foreign Application Priority Data
Dec. 26, 2022 (JP) 2022-208870
Aug. 1, 2023 (JP) 2023-125747

(51) Int. Cl. B25J 19/00

(52) U.S. Cl. CPC B25J 19/00; H01L 21/68707

(57) ABSTRACT

A cover includes: a covering part which covers a gripping part of a robot hand and which is constituted by an insulator; and a shielding layer which is provided inside the covering part and which is constituted by a conductor. The shielding layer covers a sensor included in the gripping part or a sensor provided in the covering part.

This Nonprovisional application claims priority under 35 U.S.C. § 119 on Patent Application No. 2022-208870 filed in Japan on Dec. 26, 2022 and Patent Application No. 2023-125747 filed in Japan on Aug. 1, 2023, the entire contents of which are hereby incorporated by reference.

### TECHNICAL FIELD

The present invention relates to a cover and a robot hand.

### BACKGROUND ART

Robot hands are used in various fields such as those of production and conveyance of objects. In such fields, a contact sensor of a capacitive type or a pressure type, for example, is attached to a gripping part (e.g., claw part) of a robot hand. The sensor then detects a force applied from the object (also called “gripping target object”) to the gripping part, that is, a force applied from the gripping part to the object. A value detected by the sensor is referred to for, for example, feedback control of a gripping force. Therefore, when a fragile gripping target object is to be gripped by a gripping part, the accuracy of the sensor is required to be sufficiently high. As techniques for increasing the accuracy of a sensor attached to a robot hand, techniques in which wiring or a circuit from a sensor is changed so as to increase the accuracy of the sensor are known (see, for example, Patent Literatures 1 and 2).

### CITATION LIST

### Patent Literature

[Patent Literature 1]
Japanese Patent Application Publication Tokukai No. 2021-167747

[Patent Literature 2]
Japanese Patent Application Publication Tokukai No. 2021-166149

### SUMMARY OF INVENTION

### Technical Problem

However, sensors of a capacitive type or a pressure type are generally susceptible to noise. Therefore, in the above conventional techniques, there are cases where noise that cannot be sufficiently absorbed by wiring or a circuit of a sensor adversely affects values detected by the sensor. In addition, when a gripping target object to be gripped by a robot hand tends to be electrically charged, a sensor provided at a gripping part of the robot hand may be affected by noise which is caused by the electric field of the charged gripping target object. In addition, various types of noise occur in a production site where robots are disposed for automation. Therefore, a sensor provided at a gripping part of a robot hand is affected by various types of noise at the production site.

As a result, there are cases where a force applied from the gripping part to the gripping target object cannot be accurately detected, so that the robot hand damages the gripping target object. In particular, although a pressure-type sensor that detects a load applied to a gripping part has the advantages of being thin and of having a simple design, the pressure-type sensor is sensitive to noise, and therefore could not be installed on a robot hand.

An object of an aspect of the present invention is to achieve a technique for suppressing a noise-caused decrease in the accuracy of a sensor for use in a gripping part of a robot hand.

### Solution to Problem

In order to attain the object, a cover in accordance with an aspect of the present invention is a cover to be attached to a gripping part of a robot hand, including: a covering part which is constituted by an insulator and which covers the gripping part of the robot hand; and a shielding layer which is constituted by a conductor and which is provided inside the covering part or on a surface of the covering part, in which (1) the gripping part is provided with a sensor, and the shielding layer is provided so as to cover the sensor or (2) the covering part is provided with a sensor, and the sensor is covered with the shielding layer.

In order to attain the object, a robot hand in accordance with an aspect of the present invention includes the cover.

### Advantageous Effects of Invention

With an aspect of the present invention, a noise-caused decrease in the accuracy of a sensor for use in a gripping part of a robot hand can be suppressed.

### BRIEF DESCRIPTION OF DRAWINGS

FIG. 1 is a view schematically illustrating a configuration of a robot hand in accordance with an embodiment of the present invention.

FIG. 2 is a view schematically illustrating a cross section of a gripping part and a cover in the area A taken along the Y-Z plane in FIG. 1.

FIG. 3 is a view schematically illustrating the cover in the area A in FIG. 1.

FIG. 4 is a view schematically illustrating a cross section of the gripping part and the cover in the area A taken along the X-Z plane in FIG. 1.

FIG. 5 is a cross-sectional view schematically illustrating an example of the cover in accordance with an embodiment of the present invention.

FIG. 6 is a cross-sectional view schematically illustrating another example of the cover in accordance with an embodiment of the present invention.

### DESCRIPTION OF EMBODIMENTS

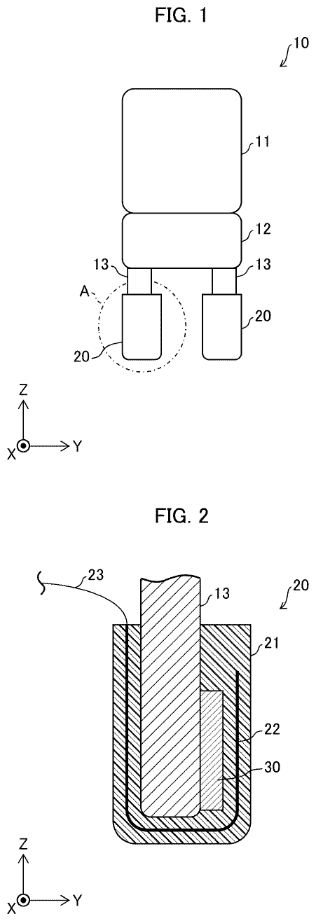

The following description will discuss an embodiment of the present invention in detail. FIG. 1 is a view schematically illustrating a configuration of a robot hand in accordance with an embodiment of the present invention.

As illustrated in FIG. 1, a robot 10 includes a robot arm 11, a robot hand 12 that is connected the tip side of the robot arm 11, and gripping parts 13 that are connected to the tip side of the robot hand 12. The robot hand 12 has a pair of (two) gripping parts 13. The gripping parts 13 are parts for gripping an object to be gripped (gripping target object), and are usually called claws or fingers in the context of a robot hand. The robot hand 12 has the pair of (two) gripping parts 13, and covers 20 are attached to the respective gripping parts 13. The gripping parts 13 are configured such that the tip parts thereof move or bend to approach each other, so as to grip a gripping target object.

In the present embodiment, a direction in which the gripping parts 13 extend is referred to as a Z direction, a direction which is orthogonal to the Z direction and in which the pair of gripping parts 13 approach each other is referred to as a Y direction, and a direction which is orthogonal to the Z direction and the Y direction and is the width direction of the gripping parts 13 is referred to as an X direction.

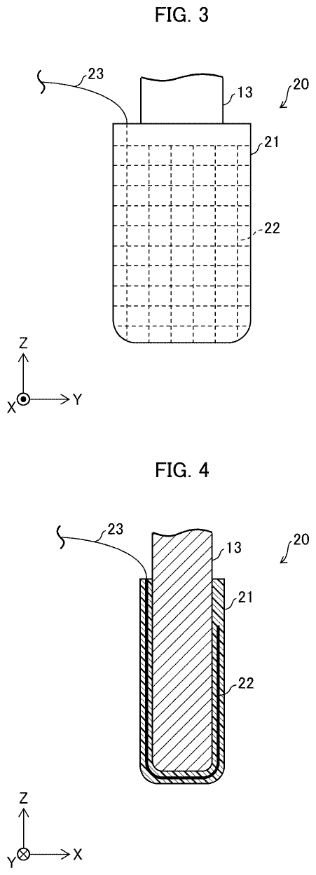

The covers 20 will be described next. FIG. 2 is a view schematically illustrating a cross section of the gripping part 13 and the cover 20 in the area A taken along the Y-Z plane in FIG. 1. FIG. 3 is a view schematically illustrating the cover 20 in the area A in FIG. 1. FIG. 3 is a front view in which the cover 20 is viewed in the X direction. FIG. 4 is a view schematically illustrating a cross section of the gripping part and the cover in the area A taken along the X-Z plane in FIG. 1. The cover 20 includes a covering part 21, a shielding layer 22, and a grounding conductive wire 23. Between the tip part of the gripping part 13 and the covering part 21, a sensor 30 is disposed.

The covering part 21 covers the entire tip part of the gripping part 13, that is, the tip surface of the gripping part 13 and the side surface of the tip part. The covering part 21 thus covers the gripping part 13. The inner surface of the covering part 21 is shaped so as to be in contact with the outer surfaces of the gripping part 13 and of the sensor 30.

The covering part 21 thus has a hollow whose shape corresponds to the outer shape of the gripping part 13 and of the sensor 30. The covering part 21 is thus configured substantially not to press against the sensor 30 when covering the gripping part 13.

The covering part 21 is constituted by an insulator. From the viewpoint of moldability and the like, the covering part 21 is, for example, a resin molded product. The covering part 21 is preferably a resin molded product from the viewpoint of easily and accurately forming the above circumscribing shape. From the viewpoint of suitably absorbing an external force against a gripping target object when the gripping parts 13 grip the gripping target object, resins of which the covering parts 21 are made of are preferably elastic. Examples of such a resin include rubbers such as fluororubber.

The shielding layer 22 is provided inside the covering part 21. The inside of the covering part 21 is not the inside of the shape formed by the covering part 21 (i.e., the hollow described later) but is the inside of the covering part 21 itself, that is, the part between the inner surface and the outer surface of the covering part 21.

The shielding layer 22 is constituted by a conductor. Examples of the conductor include metals such as aluminum, copper, and an alloy thereof. For example, as illustrated in FIG. 3, the shielding layer 22 is a mesh of a wire of the conductor, and is thus configured by the conductor being disposed in a mesh-like manner.

The dimensions of the mesh for the shielding layer 22 can be determined as appropriate, provided that detection by the sensor 30 and the removal of noise to the sensor 30 can be both achieved. For example, an excessively large wire diameter of the mesh may lead to high rigidity of the shielding layer 22, and may affect the sensitivity of the sensor 30. An excessively coarse mesh may cause the sensor 30 to be affected by noise, and may cause the removal of the noise to be insufficient. Thus, the structure of the shielding layer 22 can be determined as appropriate from the viewpoint of the rigidity and a sufficient electrostatic shielding effect of the shielding layer 22.

The shielding layer 22 spreads all over the covering part 21 inside the covering part 21. For example, as illustrated in FIG. 2 and FIG. 4, the shielding layer 22 covers substantially the entire tip part of the gripping part 13 in the Y-Z plane and in the X-Z plane that is orthogonal to Y-Z plane. The shielding layer 22 thus covers the sensor 30.

One end of the grounding conductive wire 23 is connected to the shielding layer 22, and the other end is connected to a ground. The ground differs from the ground of the sensor 30, and examples of which include the robot hand 12, the robot arm 11, and the robot body of the robot 10. The cover 20 thus further includes the grounding conductive wire 23 which is connected to the shielding layer 22 and to the ground.

The sensor 30 contact-type sensor. Examples of the sensor 30 include a capacitive sensor, a piezoelectric sensor, and a pressure-type sensor (also called a resistive film (wire-wound resistor) sensor) (pressure sensor of a film-laminated type). The sensor 30 is a tactile sensor such as a pressure sensor sheet, and is capable of detecting the distribution of a force perpendicular to the surface of the sensor 30. The sensor 30 may be constituted by, for example, a film-like base material and detection points which are disposed regularly on the surface of the base material.

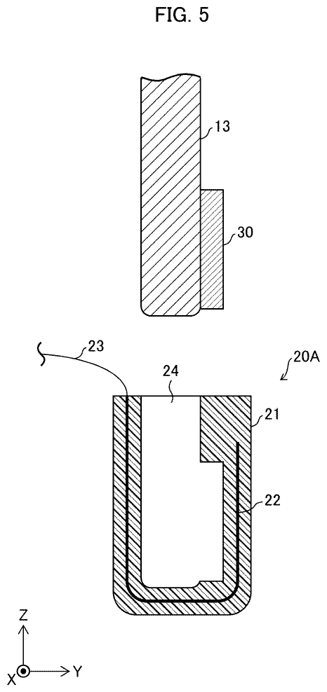

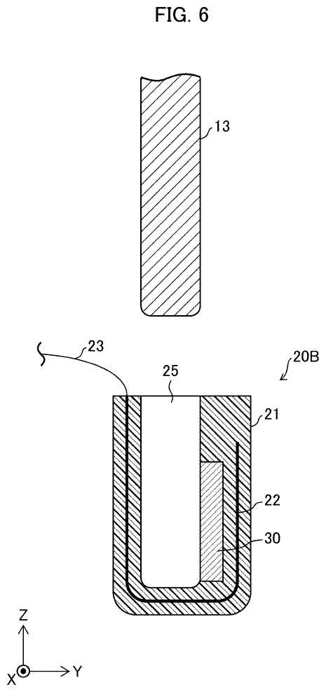

FIG. 5 is a cross-sectional view schematically illustrating an example of the cover 20 in accordance with an embodiment of the present invention. FIG. 6 is a cross-sectional view schematically illustrating another example of the cover 20 in accordance with an embodiment of the present invention. As illustrated in FIG. 5, the cover 20 is, for example, a cover 20A that is to be put on a gripping part 13 to which a sensor 30 is attached. The cover 20A illustrated in FIG. 5 is formed so as to have a cap-like shape to be put on the tip part of the gripping part 13 and the sensor 30 disposed at the tip part, and has a hollow 24 having a shape identical to the outer shape of the gripping part 13 and of the sensor 30. A shielding layer 22 is disposed inside a covering part 21 so as to surround the entire hollow 24 including a part of the hollow 24 which has a shape corresponding to the sensor 30. The cover 20A in FIG. 5 is thus configured such that the gripping part 13 is provided with the sensor 30, and the shielding layer 22 is provided so as to cover the sensor 30.

Alternatively, as illustrated in FIG. 6, the cover 20 can be a cover 20B that has a sensor 30 disposed at the position of the tip part of a gripping part 13. The cover 20B illustrated in FIG. 6 is formed so as to have a cap-like shape to be put on the tip part of the gripping part 13, and a covering part 21 has a hollow having a shape identical to that of the hollow 24 of the cover 20A. In the cover 20B, the sensor 30 is provided at a position in the hollow at which the sensor 30 faces the tip part of the gripping part 13.

As a result, in the cover 20B, a hollow 25 is formed by the inner peripheral surface of the covering part 21 and the surface of the sensor 30 which is exposed from the covering part 21. When the tip part of the gripping part 13 is inserted into the hollow 25, the cover 20B is put on the tip part of the gripping part 13. A shielding layer 22 is disposed inside the covering part 21 so as to surround the entire hollow 25 including the part of the covering part 21 where the sensor 30 is provided. Thus, in the cover 20B in FIG. 6, the covering part 21 is provided with the sensor 30, and the sensor 30 is covered with the shielding layer 22.

The cover 20A in FIG. 5 and the cover 20B in FIG. 6 can be produced by insert molding such that a molding material is the resin of which the covering part 21 is made, and an insert component(s) is, for example, a conductor mesh which is to become the shielding layer 22 and, as needed, the sensor 30.

### Main Effects

A robot 10 is one of the essential elements in automation of a production process. However, various types of noise tend to occur in such a production site where automation is implemented. Therefore, in such an automated production line, the sensors 30 of the gripping parts 13 of the robot hand 12 may be affected by various types of noise. In addition, when a gripping target object to be gripped by the gripping parts 13 of the robot hand 12 which include the sensors 30 is electrically charged, the electric charge of the gripping target object is transmitted to the sensors 30 by electrostatic induction and becomes noise.

Such various types of noise may adversely affect the detection by the sensors 30, so as to damage the gripping target object as described earlier. In particular, although a pressure-type sensor that detects a load applied to the gripping part 13 has the advantages of being thin and of having a simple design, the pressure-type sensor is sensitive to noise, and therefore could not be installed.

The robot 10 in accordance with the present embodiment includes the robot hand 12 including the covers 20. The covers 20 each include: the covering part 21 which is constituted by an insulator and which covers the gripping part 13 of the robot hand 12; and the shielding layer 22 which is constituted by a conductor and which is provided inside the covering part 21. The shielding layer 22 covers the sensor 30 with which the gripping part 13 is provided. The shielding layer 22 becomes equipotential, and is connected to a ground. Therefore, even when an electrically charged gripping target object is gripped by the gripping parts 13 having the sensors 30, the electric field caused by the gripping target object is blocked by the shielding layer 22 and therefore does not reach the sensors 30.

Therefore, when the gripping target object is gripped by the gripping parts 13, the sensors 30 are not affected by the noise of the gripping target object, and exhibit desired performance. Therefore, a decrease in the accuracy of the sensors 30 caused by noise is suppressed. Thus, providing the covers 20 on the gripping parts 13 of the robot hand 12 makes it possible to remove noise to the sensors 30. This enables accurate control of a gripping force without malfunctions.

The covering part 21 is a resin molded product that has a hollow whose shape corresponds to the outer shape of the gripping part 13 and of the sensor 30. Therefore, when the cover 20 is put on the gripping part 13, the covering part 21 is prevented from pressing against the sensor 30. This substantially prevents the installment of the cover 20 from affecting the detection by the sensor 30. In addition, because the covering part 21 is a resin molded product, a cover 20 that has a hollow with an accurate shape can be easily produced by molding, regardless of the complexity of the shape.

The shielding layer 22 is configured by a wire of the conductor being disposed in a mesh-like manner. This makes it possible to suitably and easily surround the sensor 30 with the conductor. In addition, the mesh-like configuration achieves high deformability. This further suppresses the effect of the presence of the shielding layer 22 on the detection performance of the sensor 30.

The cover 20 is connected to the shielding layer 22 and further includes the grounding conductive wire 23 which is connected to the ground. This causes the electric potential of the shielding layer 22 to be equipotential. Therefore, even when noise to the sensor 30 is great, a decrease in the accuracy of the sensor 30 due to the noise can be suppressed.

As has been described, the cover 20 in accordance with the present embodiment can suppress the effect of noise on the sensor 30. Therefore, even when a gripping target object which may generate relatively strong noise, such as a semiconductor product, is handled, a decrease in the accuracy of the sensor 30 can be suppressed. In addition, the noise of a gripping target object changes depending on the environment. Even when a gripping target object whose noise thus easily changes, such as a plastic product that is easily electrically charged, is handled, a decrease in the accuracy of the sensor 30 can be suppressed.

According to the present embodiment, in the case of the gripping parts 13 of the robot hand 12, with or without the sensors 30, it is possible to detect a gripping target object by the sensors 30 and to substantially neutralize the effect of the noise of the gripping target object on the detection by the sensors 30. Therefore, with the present embodiment, the robot hand 12 including contact-type sensors 30 can easily have a noise-resistant environment.

In addition, sensors 30 to be provided to the gripping parts 13 are of a capacitive type, a pressure type, and the like. A noise-caused decrease in the accuracy of any of these sensors can be suppressed; the present invention is thus effective. Therefore, the present invention makes it possible to provide the gripping parts 13 of the robot hand 12 with pressure-type sensors. This enables the robot hand 12 to accurately grip a gripping target object, and achieve high responsivity so as to improve the performance of the robot hand 12.

### Variations

The number of the gripping parts 13 of the robot hand 12 can be two or more, for example, three. A sensor 30 can be attached to all of the plurality of gripping parts 13, or can be attached only to some of the gripping parts 13. The cover 20 is put on a gripping part(s) 13 to which the sensor 30 is attached.

The covering part 21 can be made of another material, provided that the material has an insulating property. When the covering part 21 is a resin composition, the resin composition does not need to be elastic, and can be a rigid resin composition.

The covering part 21 can further include a structure for the attachment to the gripping part 13. For example, the covering part 21 can further include a hinge structure such that the covering part 21 is divided along the Z direction as appropriate and that the part at which the covering part 21 is divided is supported so as to be opened and closed. Such a structure is suitable in that, even when the outer shape of the gripping part 13 and of the sensor 30 is complex, the covering part 21 that corresponds to the outer shape can be easily and accurately attached to the gripping part 13.

The covering part 21 can have a part that is sufficiently away from the sensor 30 and that shrinks toward the gripping part 13. For example, the covering part 21 can be elastic and formed such that only an opening of the covering part 21 is slightly narrow, so that the cover 20 is attached to the gripping part 13 by pressing against and coming into close contact with the gripping part 13 when being put on the gripping part 13. This structure is suitable in that the cover 20 can be easily attached to the gripping part 13.

Alternatively, the covering part 21 can be adhered to the gripping part 13 with an adhesive. Alternatively, the cover 20 can be attached to the gripping part 13 with a fastening member such as a rubber band or a belt which tightens the covering part 21 on the gripping part 13.

The covering part 21 can have a double-structure having an inner structure and an outer structure, and the shielding layer 22 can be disposed between the inner structure and the outer structure. Such a structure makes it possible to adjust the spreading of the shielding layer 22 and is therefore suitable in that the range where the shielding layer 22 covers the sensor 30 can be adjusted as appropriate.

When the surface of the sensor 30 is sufficiently insulating (e.g., when an insulating coating film is formed), the shielding layer 22 can be exposed to the inner surface of the covering part 21.

The material and the form of the shielding layer 22 can be set as appropriate, provided that electrostatic shielding of the sensor 30 is sufficient. For example, the shielding layer 22 can be provided only at a part that overlaps the sensor 30 when viewed in the Y direction.

The shielding layer 22 can have a form other than a mesh formed by a conductor, provided that the effects of the present embodiment can be achieved. For example, the shielding layer 22 can be a foil of a conductor, a coil of a conductor, or wiring that has been printed by a coating material of conductor particles such as silver nanoparticle ink.

In the cover 20B illustrated in FIG. 6, wiring for the sensor 30 can be further disposed in the covering part 21 as a wiring that is independent of the shielding layer 22. Such a cover 20B can be produced by further including wiring for the sensor 30 in an insert component during the above-described insert molding.

Aspects of the present invention can also be expressed as follows:

As is apparent from the above descriptions, a cover (20) in accordance with a first aspect of the present invention is a cover to be attached to a gripping part (13) of a robot hand (12), including: a covering part (21) which is constituted by an insulator and which covers the gripping part of the robot hand; and a shielding layer (22) which is constituted by a conductor and which is provided inside the covering part or on a surface of the covering part, in which (1) the gripping part is provided with a sensor (30), and the shielding layer is provided so as to cover the sensor or (2) the covering part is provided with a sensor, and the sensor is covered with the shielding layer. With the first aspect, a noise-caused decrease in the accuracy of a sensor for use in a gripping part of a robot hand can be suppressed.

In a second aspect of the present invention, the cover in accordance with the first aspect is configured such that the covering part is a resin molded product that has a hollow whose shape corresponds to an outer shape of the gripping part and of the sensor. The second aspect is even more effective from the viewpoint of suppressing the effect of the attachment of a cover on the detection function of a sensor and from the viewpoint of accurately and easily producing a cover.

In a third aspect of the present invention, the cover in accordance with the first aspect or the second aspect is arranged such that the shielding layer is configured by a wire of the conductor being disposed in a mesh-like manner. The third aspect is even more effective from the viewpoint of suppressing the effect of noise of a gripping target object and suppressing the effect on the detection performance of a sensor.

In a fourth aspect of the present invention, the cover in accordance with any one of the first aspect to the third aspect is configured to further include a grounding conductive wire (23) which is connected to the shielding layer and is connected to a ground. The fourth aspect is even more effective from the viewpoint of stably suppressing a noise-caused decrease in the accuracy of a sensor.

A robot hand in accordance with a fifth aspect of the present invention includes the cover in accordance with any one of the first aspect to the third aspect. With the fifth aspect, a noise-caused decrease in the accuracy of a sensor for use in a gripping part of a robot hand can be suppressed, as in the first aspect.

The above configurations make it possible, in the technique for automation by a robot hand, to easily establish an environment in which a contact sensor is not affected by noise. The present invention is therefore expected to contribute to achievement of, for example, Goal 9 pertaining to “industry, innovation and infrastructure” in Sustainable Development Goals (SDGs) proposed by the United Nations.

The present invention is not limited to the above embodiments, but can be altered in various ways within the scope of the claims. The present invention also encompasses, in its technical scope, any embodiment derived by appropriately combining technical means disclosed in differing embodiments.

1. A cover to be attached to a gripping part of a robot hand, comprising:
a covering part which is constituted by an insulator and which covers the gripping part of the robot hand; and
a shielding layer which is constituted by a conductor and which is provided inside the covering part or on a surface of the covering part, wherein
(1) the gripping part is provided with a sensor, and the shielding layer is provided so as to cover the sensor or (2) the covering part is provided with a sensor, and the sensor is covered with the shielding layer.

2. The cover according to claim 1, wherein the covering part is a resin molded product that has a hollow whose shape corresponds to an outer shape of the gripping part and of the sensor.

3. The cover according to claim 1, wherein the shielding layer is configured by a wire of the conductor being disposed in a mesh-like manner.

4. The cover according to claim 1, further comprising a grounding conductive wire which is connected to the shielding layer and is connected to a ground.

5. A robot hand comprising the cover according to claim 1.

6. A robot hand comprising the cover according to claim 2.

7. A robot hand comprising the cover according to claim 3.

8. A robot hand comprising the cover according to claim 4.
